(19) United States
(12) Patent Application Publication
(10) Pub. No.: US 2014/0347906 A1
(43) Pub. Date: Nov. 27, 2014

(54) TCAM MEMORY CELL AND COMPONENT INCORPORATING A MATRIX OF SUCH CELLS

(71) Applicant: STMicroelectronics SA, Montrouge (FR)

(72) Inventors: Olivier Menut, Saint-Martin-d'Heres (FR); David Turgis, Le Touvet (FR); Lorenzo Ciampolini, Grenoble (FR)

(73) Assignee: STMICROELECTRONICS SA, Montrouge (FR)

(21) Appl. No.: 14/280,833

(22) Filed: May 19, 2014

(30) Foreign Application Priority Data
May 24, 2013 (FR) 1354713

(51) Int. Cl. G11C 15/04

(52) U.S. Cl. CPC G11C 15/046
USPC 365/49.17

(57) ABSTRACT

A ternary content-addressable cell is configured to compare an input binary data item present on an input terminal with two reference binary data items, and to output a match signal on a match line. The cell includes: a first storage circuit (storing a potential representing the first reference binary data item) and a second storage cell (storing a potential representing the second reference binary data item). A comparison circuit is connected to the first and second storage circuits and to the input terminal SL. A comparison node presents a potential representing the comparison of the input binary data item with the first and second reference data items. The comparison node is connected to an output stage, and the output stage is connected to the match line. The signal on the match line is based on the potential of the comparison node.

### PRIORITY CLAIM

This application claims priority from French Application for Patent No. 1354713 filed May 24, 2013, the disclosure of which is incorporated by reference.

### TECHNICAL FIELD

The invention concerns the field of microelectronics—more precisely that of memory circuits and, more specifically, content-addressable memory components, notably ternary content. More particularly, the invention concerns architectures for this type of memory allowing for improved performance in terms of operating speed and/or power consumption.

### BACKGROUND

Memory components of CAM (“Content-Addressable Memory”) type are memory components that allow a comparison between a set of data to search and a set of pre-recorded data (or key data), so as to detect a correspondence between the data searched and the pre-recorded data.

This kind of memory has an appropriate application in routing systems, in which the address of a data packet recipient must be identified in the list of addresses of possible recipients recorded within a system, so that the packet is routed via the port of the device to which the installation of the address is being searched is connected.

To do this, CAM-type memory components have a number of cells arranged in a matrix of lines and columns. Conventionally, each line contains the different bits of a data word for which the comparison with the key data is performed bit by bit, at the level of each cell. Conventionally, therefore, each cell incorporates a memory point within which the corresponding bit of the key data word is recorded, and a comparison circuit allowing the pre-recorded data bit to be recorded with the same-magnitude bit of the data to be searched.

When the comparison is positive, i.e. when the bit of the key data item matches with the same-magnitude bit of the searched data item, then the comparison circuit sets a comparison point to a given state—generally low—of a match line, shared between the different bits of the same word, i.e. of a same line. Because this match line is shared by all the cells of a given line, its potential is at the given level—typically low—when all the cells of a given line return a bit-to-bit match.

Among the various existing CAM memory components, a particular type called TCAM (“Ternary Content-Addressable Memory”) enables one to implement more-sophisticated comparison functions. In particular, with this type of memory, it is possible to conclude on a match without taking account of the value of all or part of the bits of a data word to be searched.

In other words, certain cells of the memory are configured to send a match signal regardless of the level of all or part of the bits of a word.

To implement this function of masking certain bits, it is possible to implement a particular architecture of cells, in which each cell incorporates two memory points or storage circuits, so as to compare the value of the bit to be searched with the value of the pre-recorded bit and its complement, which are each stored in their memory point.

More precisely, the comparison circuit verifies that the key data bit is at a high level at the same time as the bit of the first memory point, or that the complement of the key data word bit is also at a level at the same time as the second memory point, in which the complement of the bit recorded in the first memory point is nominally recorded.

However, when the first and second memory points are not saved with complementary data, the comparison circuit can issue a match signal regardless of the level of the input bit and its complement.

In practice, in CMOS technology, the comparison circuits are implemented using N-MOS-type transistors arranged to implement an “exclusive OR” function between the data from, firstly, the two memory points and, secondly, the input bit and its complement.

Yet, one can conceive that an increase in the capacity of CAM memory components, i.e. the quantity of key data items with which a search data item must be compared, gives rise to an increase in the power consumed by the memory, because all the comparison circuits are active during the search operations. This tendency towards an increase in power consumption is even more sensitive with the increase in operating frequencies. This is because, to enable the comparison circuit to operate at a higher frequency, it is necessary to use transistors that switch quickly, and that have a considerable output current. Thus, these transistors are relatively large, which augments their interference capability and, therefore, the overall power consumed.

### SUMMARY

It would therefore be desirable to have a TCAM memory architecture that can operate at higher frequency and/or with big capacities in terms of size of key data items, and that can achieve this without excessively increasing the power consumed—or even with a power consumption decrease.

To attain all or part of these objectives, and to achieve other objectives, one implementation incorporates a ternary content-addressable memory cell that is configured to compare an input binary data item present on the cell's input terminal with two reference binary data items, and to output a match signal on a match line to which the said cell is connected, with the said cell including: an initial storage circuit of which one point is at a potential that represents the first reference binary data item; a second storage circuit of which one point is at a potential representing the second reference binary data item; a comparison circuit connected to the said points of the first and second storage circuits, and to the said input terminal of the cell, and having a comparison point of which the potential represents the comparison of the input binary data item with the first and second reference data items, in which the said comparison point is connected to an output stage, with the said output stage being connected to the match line, and configured to output on the match line a signal based on the comparison point's potential.

In another implementation, one can have a second input terminal to which a data item complementing the said input binary data item is applied.

In one implementation, the comparison circuit incorporates transistors arranged so that the comparison point is at a low potential if one of the following two conditions is fulfilled: the input binary data item is equal to the first reference binary data item; and the complement of the input binary data item is equal to the second reference binary data item.

In one implementation, the output stage incorporates a transistor of P-MOS type of which the gate is connected to the said comparison point, and of which the drain is connected to the match line.

In one implementation, the cell also includes a charging circuit controlled by a signal that indicates whether or not the comparison is enabled, and configured to connect the comparison point to a power source when the signal indicating authorization of the comparison is at a level corresponding to a non-authorization of the comparison.

In one implementation, the charging circuit also includes a transistor that connects the low point of the comparison circuit with a reference potential when the signal indicating authorization of the comparison is at a level corresponding to an authorization of the comparison.

One can also provide an integrated circuit incorporating a matrix of cells such as mentioned above, organized into at least one line of cells, each intended to compare the binary data item of a data word bit, in which all or part of the cells of a given line present the comparison point of their comparison circuit connected to a common output stage.

In one implementation, all or part of the cells of a given line present the low point of their comparison circuit connected to a stage of common virtual mass.

### BRIEF DESCRIPTION OF THE DRAWINGS

Certain aspects of the invention—particularly its characteristics and advantages—will come to the fore in the description that follows of special implementations provided as non-limitative illustrations, to document the appended figures, in which:

FIG. 1 is a simplified schematic of a TCAM memory cell; and

FIG. 2 shows part of the TCAM memory cells matrix in FIG. 1.

### DETAILED DESCRIPTION OF THE DRAWINGS

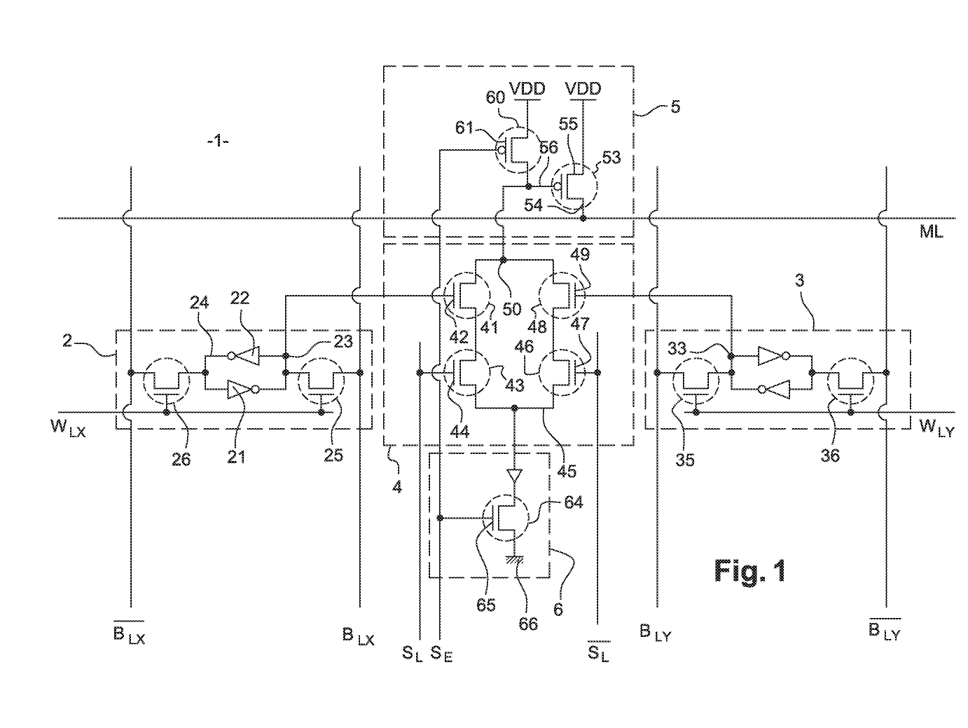

The example illustrated in FIG. 1 is a TCAM memory cell of XY type, i.e. in which the data item to search for (and its complement) are compared with two memory points. However, the principles described for this XY TCAM memory can apply to other types of CAM memory through transposition of the same principles.

As illustrated in FIG. 1, cell 1 incorporates two memory points—2 and 3—associated with a comparison circuit 4, which itself is connected at its low point to a virtual-mass circuit 6, and at its high point to an output stage 5.

Each of the memory points 2 and 3 have a conventional composition incorporating two inverters—21 and 22—mounted anti-parallel, of which the connection points—23 and 24—are at a potential representing the data item stored in the memory point 2, also referred to as a “storage circuit”.

The common points—23 and 24—of connection of the inverters—21 and 22—are connected by transistors—25 and 26—to BLX and /BLX bit lines. These BLX and /BLX bit lines enable writing and reading of the memory point 2, when the pass-gate transistors—25 and 26—are set to pass by application of the appropriate instruction on the WLX word line.

Obviously, the memory point—described here with a structure of 6T type including six transistors—can be replaced by other types of memory points incorporating, for example, more transistors.

The second memory point 3 of the cell has a composition identical to that of the memory point 2. The pass-gate transistors—35 and 36—are respectively connected to the BLY and /BLY bit lines, to enable the read/write operations on this memory point, when the WLY word line is at an appropriate potential.

Obviously, it is possible to make the two memory points depend on the same word line controlling reading/writing or, as in the form illustrated, have the word lines dedicated to just one half of the memory points of the cells assigned to a given word.

Similarly, in the illustrated form, the BLX and BLY bit lines of the two memory points—2 and 3—are separate and independent, which enables the two memory points—2 and 3—to be assigned totally-separate data items.

However, in certain TCAM memory configurations, it is possible for the two bit lines to be shared, so that the two memory points are powered by the same data items, with the comparison circuit being connected at two complementary points. However, the implementation such as illustrated in FIG. 1 allows one to conduct more-sophisticated comparisons—notably masking providing a match signal for any level at the level of the bit to be searched.

In the implementation in FIG. 1, the comparison circuit 4 is composed of four transistors which, in the illustrated form, are of N-MOS type.

A first transistor 41 presents its gate 42, which is connected to point 23 of the memory point 2. Thus, this transistor is set to pass when the data item present on the memory point 2 is at 1 (or, more generally, at high level). It is blocked when this memory point is at 0 (or, reciprocally, at a low level).

The source of the transistor 41 is connected to the drain of the transistor 43, of which the gate 44 is connected to the SL line to which is applied the input binary data item to be searched for. Thus, when this data item is set to 1, transistor 44 passes, and blocks when this data item is at 0. The source of the transistor 44 is connected to a low point 45, to which is also connected the source of transistor 46, of which the gate 47 is connected to the /SL line to which is applied the complement of the data item applied to the SL line.

In other words, the transistor 46 passes when the data item applied to the SL line is at 0 and, conversely, blocks when the data item on SL is at 1.

The drain of the transistor 46 is connected to a transistor 48 of which the gate 49 is connected to the point 33 of the memory point 3. Thus, this transistor passes when the data item stored at memory point 3 is at 1, and blocks when it is at 0.

The drains of the transistors 41 and 48 are connected to a common point 50—also referred to as a comparison point—which is at a level corresponding to the comparison of the data item present on the SL search bit line (and its complement /SL) with the values stored in the memory points 2 and 3.

Thus, when the data item present on the SL line is at 1, and when the data item present at the memory point 2 is also at 1, the branch formed from transistors 41 and 43 sets the point 50 to the potential of the low point 45.

The two transistors of the other branch—namely transistors 48 and 46—are blocked. Similarly, when the memory point 2 stores a zero value, the transistor 41 is blocked, as is the transistor 46, because the value on the /SL line is set to 0.

Consequently, the point 50 remains at a high potential imposed by the charging circuit, which will be described further on. Therefore, this high potential corresponds to a non-match of the data item circulating on the SL line and on the memory point 2. In the special configuration in which the two memory points 2 and 3 store 1 values, one or other of the transistors 43 and 46 passes, so that the point 50 is connected to the low point 45, regardless of the value circulating on the SL search line, which corresponds to a match case, regardless of the value of the bit searched for, which is also referred to as an “always-hit” configuration.

Conversely, in the other special configuration in which the two memory points—2 and 3—store zero values, the two transistors 43 and 46 are blocked and, regardless of the status of the SL search line (or its complement /SL), the comparison point 50 remains at a charged level, which corresponds to a non-match (or “always-miss”) case.

Obviously, the operation of the cell as a function of the pre-recorded values—i.e. the associated truth table—depends on the point at which the point at which the value of the memory point in relation to the SL line is sampled. That is to say the truth table associated depends on where the value is taken of the memory compared to the SL line.

The comparison point 50—of which the potential therefore corresponds to the comparison of the different data items to be compared—is connected to an output stage 5. This output stage incorporates a transistor of P-MOS type, of which the gate 56 is connected to the comparison point 50. The source of the transistor 53 is connected to a reference high potential VDD. The drain 54 of the transistor 53 is connected to the ML line on which the match information is collected for all the cells of a given word.

Thus, when the comparison point 50 is at a low potential, the transistor 53 passes and the ML line is at a high level. When all the cells of a given line detect a correspondence, all the circuits connected to the match line ML set its potential to a high value, which is then detected at a signal formatting circuit (not illustrated) transiting on the ML line.

Conversely, in the event of a non-match, the comparison point 50 changes to a high potential, such that the transistor 53 is blocked, and the ML line remains at a low potential.

The use of a common transistor controlled by the comparison circuit allows one to downsize the transistors of the comparison circuit, since these transistors do not need to output a big current since they do not directly control the match line.

This is because, since these transistors 41, 43, 46 and 48 do not need to output a big current, it is possible to use small transistors, allowing them to be recharged relatively quickly because of their low interference capacity.

Consequently, only the transistor 53 needs to be of big size sufficient to power the ML line.

In a complementary manner, the output stage 5 incorporates means of recharging the transistors of the comparison circuit stage. These means can be composed—as illustrated in FIG. 1—of a transistor 60 of P-MOS type, of which the source is connected to a high power potential VDD, and of which the drain is connected to the point 50 of the comparison point 50 of the comparison circuit 4.

The gate 61 of the transistor 60 is connected to an SE (for “Search Enable”) line, to which a signal is applied that allows comparisons between the input data items and the recorded data items to be enabled or interdicted. More precisely, this signal SE is set to 1 when search operations are to be performed. Thus, during the standby phase, during which search operations should not be conducted, the transistor 60 passes since its gate 61 is at a low potential.

Consequently, the high potential VDD is applied to the various transistors of the comparison stage 4, and they are thus polarized.

Subsequently, when the circuit changes to a search phase and the signal SE changes to high level, the transistor 60 blocks and the gate 56 of the transistor 53 is then controlled only by the potential of the comparison point 50.

To prevent any abnormal operation during the phases of polarization of the transistors of the comparison circuit 4, the low point 45 of the comparison circuit is connected to the ground 66 by means of a circuit 6, which mainly incorporates an N-MOS transistor of which the gate 65 is controlled by the SE line.

Thus, during the polarization phase, when the SE signal is set to 0, the transistor 64 is blocked and the polarization is performed by means of the transistor 60 vis-a-vis interference capacities.

Conversely, when searches are enabled and the SE signal is at a high level, the low point 45 of the comparison circuit is connected to ground.

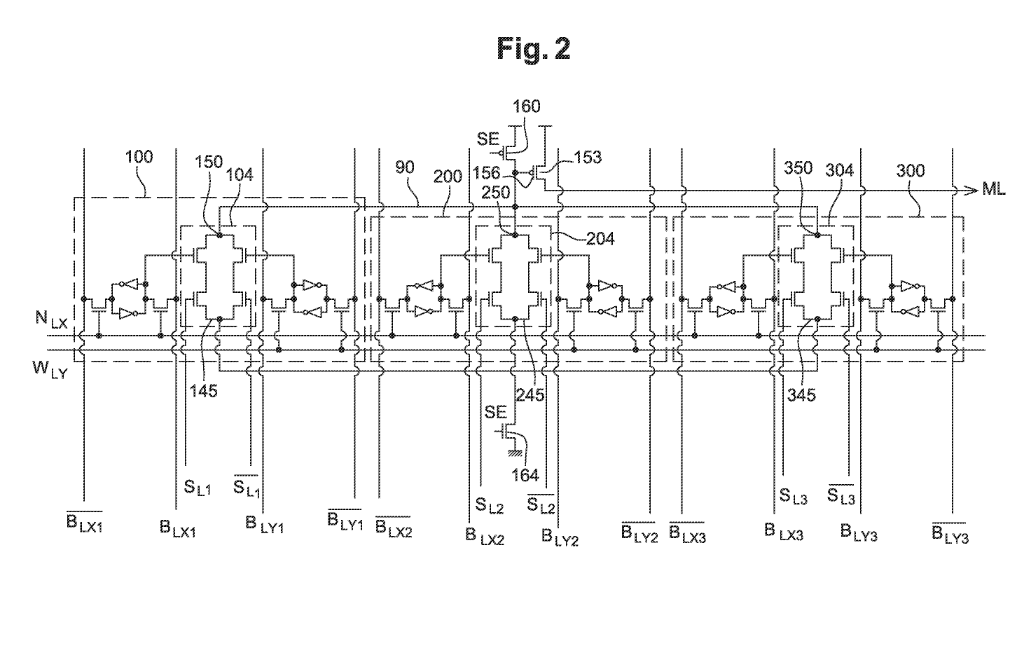

In another implementation, and as illustrated in FIG. 2, the control over the power stage can be shared between the various cells of a given word. More precisely, the cells 100, 200 and 300—which each have a comparison point 150, 250 and 350 for their comparison circuit 104, 204 and 304—can see these different points connected to a common output stage designed in a manner similar to that described for FIG. 1.

Thus, the P-MOS transistor 153 can see its gate 156 connected to all the comparison points 150, 250 and 350 at a common connection 90, at which a kind of “hard-wired AND” is performed for all the comparisons performed by the cells concerned.

In the same way, the means allowing the polarization of the various transistors of the comparison circuits 104, 204 and 304 can also be shared—at the transistor 160, for instance—controlled in the same way as in the explanations pertaining to the Figure via the SE line enabling or interdicting the comparison phases.

In parallel, all the low points 145, 245, 345 of the various comparison circuits of the circuits concerned can be linked via a same virtual mass circuit during the comparison phases—for example, by means of the transistor 164.

Obviously, the number of cells concerned within a given word can be adapted according to the powers necessary and the current values that can be supplied by each of the cells and the transistor connected to the match line. Thus, it is possible to ensure that all the cells connected to a given word are connected to a common output stage, or that the cells assigned to a given word are grouped into subsets each of which is assigned to a circuit stage shared by several cells.

It can be seen from the above explanations that the implementations described allow one to design TCAM memory components that consume particularly little current in relation to the memory components of current art. For example, it is feasible, thanks to the saving achieved by the above-stated arrangements, to reduce the dynamic power consumed by cells by a factor of three or four, while increasing the operating frequency by a factor of 3 and also increasing the global capacities of the memory in terms of number of cells.

What is claimed is:

1. An apparatus including a ternary content-addressable memory cell configured to compare an input binary data item present at an input terminal of the cell with two reference binary data items and to output a match signal through a match line to which the said cell is connected, with the memory cell comprising:
a first storage circuit of which a first point is at a potential representing the first reference binary data item;
a second storage circuit of which a second point is at a potential representing the second reference binary data item; and
a comparison circuit connected to the first and second points and to the input terminal of the cell and having a comparison point of which the potential represents the comparison of the input binary data item with the first and second reference data items, in which the comparison point is connected to an output stage, with the output stage being connected to the match line, and is configured to output a signal on the match line based on the potential of the comparison point.

2. The apparatus according to claim 1, in which there is a second input terminal to which is applied a data item complementing the said input binary data item.

3. The apparatus according to claim 2, in which the comparison circuit incorporates transistors arranged so that the comparison point is at a low potential if one of the following two conditions is fulfilled:
the binary data item is equal to the first reference binary data item; or
the complement of the input binary data item is equal to the second reference binary data item.

4. The apparatus according to claim 1, in which the output stage incorporates a transistor of P-MOS type of which the gate is connected to the comparison point and of which the drain is connected to the match line.

5. The apparatus according to claim 1, also including a charging circuit controlled by a signal indicating whether or not the comparison is enabled, and configured to connect the comparison point to a power source when the signal indicating authorization of the comparison is at a level corresponding to a non-authorization of the comparison.

6. The apparatus according to claim 1, in which the charging circuit also includes a transistor connecting the low point of the comparison circuit with a reference potential when the signal indicating enabling of the comparison is at a level corresponding to enabling of the comparison.

7. The apparatus according to claim 1, wherein a plurality of the memory cells are arranged in a matrix of cells, organized into at least one line of cells of which each is intended compare the binary data item of a data word bit, in which all or part of the cells of a given line have the comparison point of their comparison circuit connected to a common output stage.

8. The apparatus according to claim 7, in which all or part of the memory cells of the line have the low point of their comparison circuit connected to a common virtual mass stage.

9. An apparatus, comprising:
a first memory cell having a first data storage node;
a second memory cell having a second data storage node;
a comparison circuit having:
a first transistor with a first gate coupled to the first data storage node;
a second transistor having a second gate coupled to the second data storage node; and
wherein the first and second transistors have source-drain paths coupled at a first common node; and
an output circuit comprising a third transistor with a third gate coupled to the first common node and a source-drain path coupled to a match line output.

10. The apparatus of claim 9 wherein the comparison circuit further comprises:
a fourth transistor having a source-drain path coupled in series with the source-drain path of the first transistor and a fourth gate coupled to receive a search signal; and
a fifth transistor having a source-drain path coupled in series with the source-drain path of the second transistor and a fifth gate coupled to receive a complementary search signal.

11. The apparatus of claim 10, wherein the source-drain paths of the fourth and fifth transistors are coupled at a second common node.

12. The apparatus of claim 11, further comprising a virtual mass circuit comprising a seventh transistor having a source-drain path coupled to the second common node and a seventh gate terminal coupled to receive an enable signal.

13. The apparatus of claim 12, further including an eighth transistor having a source-drain path coupled to the first common node and a gate coupled to receive said enable signal.

14. The apparatus of claim 9 further including bit lines selectively coupled to the first and second data storage nodes in response to first and second word line signals, respectively.
